(19) United States
(12) Patent Application Publication
(10) Pub. No.: US 2026/0334204 A1
(43) Pub. Date: Oct. 22, 2026

(54) SEMICONDUCTOR DEVICE AND METHOD FOR MANUFACTURING THE SAME

(71) Applicant: TAIWAN SEMICONDUCTOR MANUFACTURING COMPANY LTD., HSINCHU (TW)

(72) Inventors: KUAN YU CHEN, HSINCHU CITY (TW); WEI-CHENG TZENG, TAIPEI (TW); CHUN-HSUAN WANG, HSINCHU COUNTY (TW); WEI-CHENG LIN, TAICHUNG CITY (TW); YI-KAN CHENG, TAIPEI (TW); YUNG-CHIN HOU, TAIPEI (TW)

(21) Appl. No.: 19/182,677

(22) Filed: Apr. 18, 2025

(51) Int. Cl. H10W 20/41; H10W 20/42; H10W 20/43

(52) U.S. Cl. CPC H10W 20/427; H10W 20/42; H10W 20/43; H10W 20/435

(57) ABSTRACT

A semiconductor device and a method for manufacturing the semiconductor device are provided. The semiconductor device includes a plurality of first power lines, a plurality of second power lines, a plurality of third power lines and a power tap cell. The first power lines are formed on a front side of a substrate and extend in a first direction. The first power lines are electrically connected to a first set of cells and a second set of cells. The first set of cells are configured to receive a first voltage, and the second set of cells are configured to receive a second voltage smaller than the first voltage. The second power lines are formed on the front side of the substrate, extend in a second direction vertical to the first direction, and are electrically connected to the first set of cells.

### BACKGROUND

The present disclosure relates, in general, to semiconductor devices and methods for manufacturing the same. Specifically, the present disclosure relates to semiconductor devices and methods for manufacturing semiconductor devices with various power supplies and power transmission paths.

Integrated circuits that involve semiconductor devices are essential for many modern applications. Technological advances in materials and design have led to the production of semiconductor devices with smaller and more complex elements in each generation. Although miniaturization and voltage reduction per element have reduced power consumption, the overall power consumption of the integrated circuit is increasing due to the growing number of elements. As a result, a novel design for a semiconductor device, used as a power switch cell, is needed to control power delivery and enhance design flexibility.

### BRIEF DESCRIPTION OF THE DRAWINGS

Aspects of the embodiments of the present disclosure are best understood from the following detailed description when read with the accompanying figures. It should be noted that, in accordance with standard practice in the industry, various structures are not drawn to scale. In fact, the dimensions of the various structures can be arbitrarily increased or reduced for clarity of discussion.

FIG. 1A is a schematic view of a design layout of a semiconductor device, in accordance with some embodiments of the present disclosure.

FIG. 1B is a schematic view of a design layout of another semiconductor device, in accordance with some embodiments of the present disclosure.

FIG. 2 is a schematic diagram of a semiconductor device, in accordance with some embodiments of the present disclosure.

FIG. 3 illustrates a cross-section view of a semiconductor device, in accordance with some embodiments of the present disclosure.

FIG. 4A illustrates a cross-section view of a semiconductor device, in accordance with some embodiments of the present disclosure.

FIG. 4B illustrates a cross-section view of another semiconductor device, in accordance with some embodiments of the present disclosure.

FIG. 4C illustrates a cross-section view of another semiconductor device, in accordance with some embodiments of the present disclosure.

FIG. 5 illustrates a cross-section view of a semiconductor device, in accordance with some embodiments of the present disclosure.

FIG. 6A illustrates a cross-section view of a semiconductor device, in accordance with some embodiments of the present disclosure.

FIG. 6B illustrates a cross-section view of another semiconductor device, in accordance with some embodiments of the present disclosure.

FIG. 7 illustrates a cross-section view of a semiconductor device, in accordance with some embodiments of the present disclosure.

FIG. 8 is a schematic diagram illustrating the speed and switch power of a semiconductor device, in accordance with some embodiments of the present disclosure.

FIG. 9 illustrates a flow chart including a method for manufacturing the semiconductor device, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as "first," "second" and "third" describe various elements, components, regions, layers and/or sections, these elements, components, regions, layers and/or sections should not be limited by these terms. These terms may only be used to distinguish one element, component, region, layer or section from another. Terms such as "first," "second" and "third" when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms "substantially," "approximately" and “about” generally mean within a value or range that can be contemplated by people having ordinary skill in the art. Alternatively, the terms "substantially," "approximately" and "about" mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms "substantially," "approximately" or "about." Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

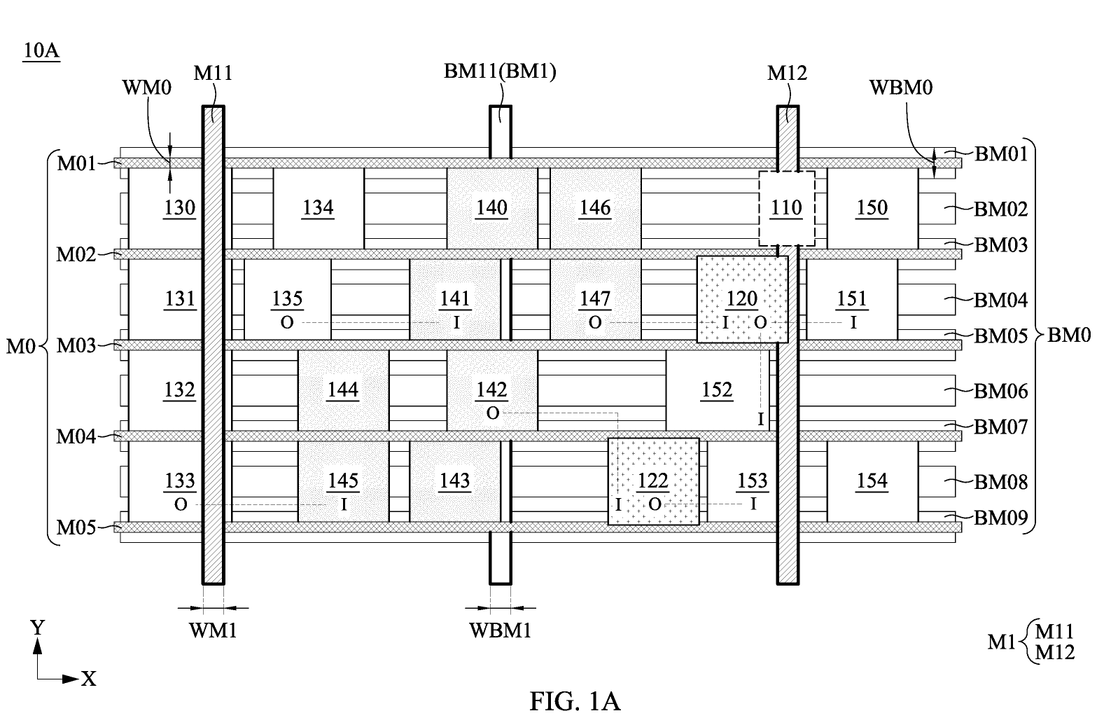

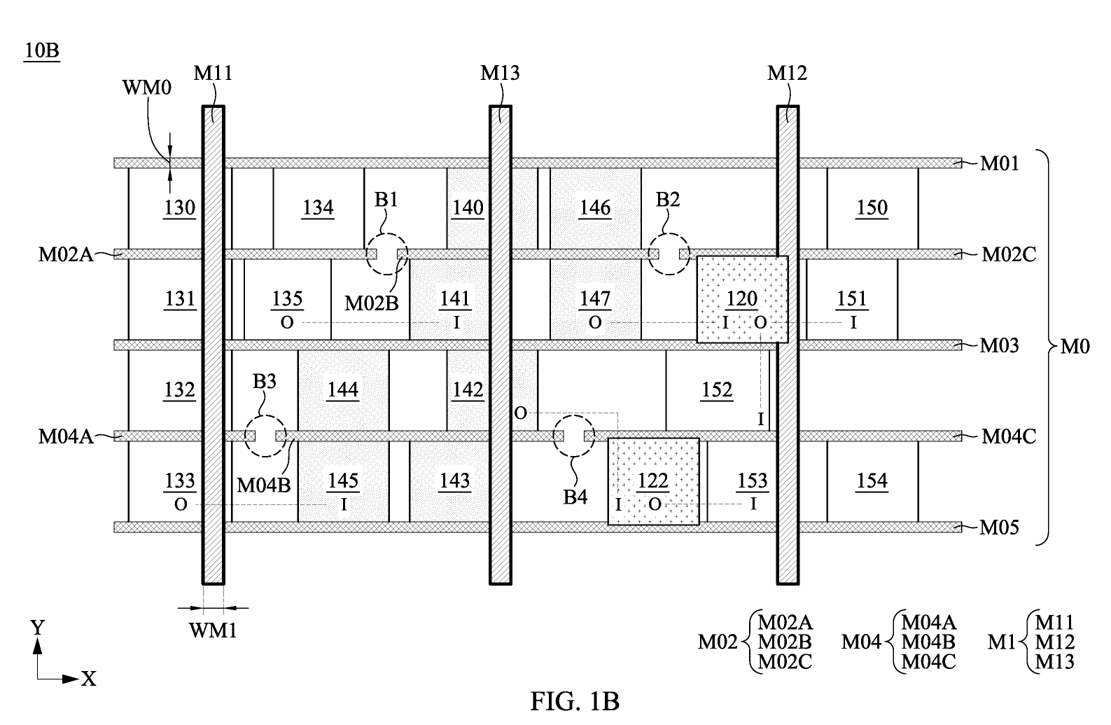

FIG. 1A is a schematic view of a design layout of a semiconductor device 10A, in accordance with some embodiments of the present disclosure. The semiconductor device 10A can be, for example, an N-type metal-oxide-semiconductor (NMOS) device, a P-type metal-oxide-semiconductor (PMOS) device, a complementary metal-oxide-semiconductor (CMOS) device, and can be implemented using a planar field-effect transistor (FET) device, a fin-type FET (FinFET) device, a gate-all-around (GAA) device, a nanowire device, a fully-depleted silicon-on-isolator (FDSOI) device, or the like. The semiconductor device 10A can be formed on a wafer including a substrate and optionally various semiconductor layers formed thereon.

The metal structures M0 and M1 are on the front side of the substrate, and the metal structures BM0 and BM1 are on the back side of the substrate opposite to the front side. The semiconductor device 10A can belong to a super power rail (SPR) chip design which includes or provides a power delivery network (PDN) through the front side and the back side of the substrate. The semiconductor device 10A can include a virtual power domain and a true power domain. The true power domain is configured to transmit power from a power supply or a power source to a header cell. The virtual power domain is configured to transmit power from the header cell to a standard cell or a functional cell which includes various kinds of logic gates or electronic elements. The metal structures M0, M1, BM0 and BM1 can correspond or belong to the true power domain or the virtual power domain to allocate or distribute the power from the front side and the back side of the substrate.

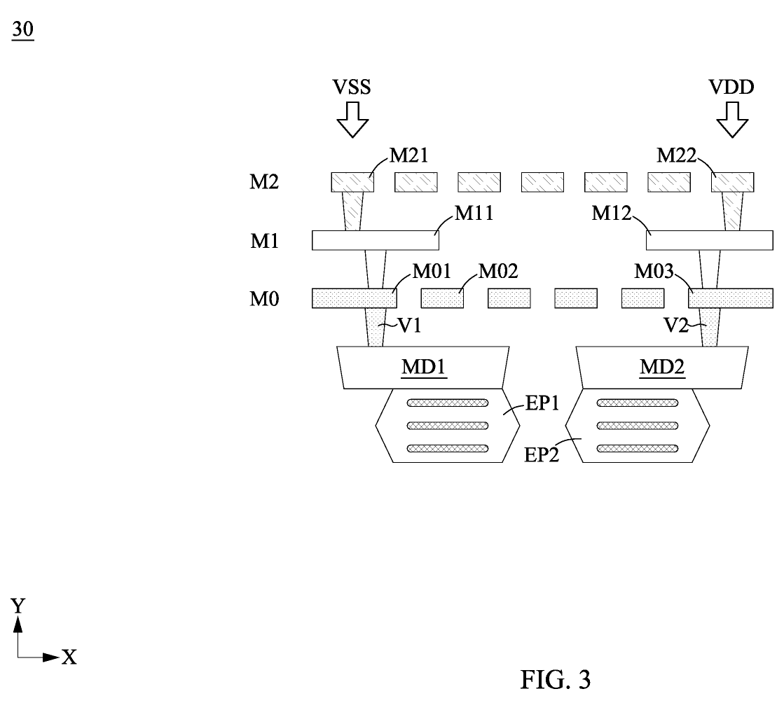

The semiconductor device 10A can include multiple metal structures M0, M1, BM0 and BM1 in different elevation levels. More specifically, from the perspective of a cross-sectional view, as indicated in FIG. 3, the metal structure M1 can be formed above the metal structure M0. In addition, the metal structure BM0 can be formed above the metal structure BM1. The metal structures M0, M1, BM0 and BM1 are made of metal, such as copper, aluminum, tungsten, titanium, tantalum, an alloy thereof or the like, and are electrically insulated by dielectric materials such as oxide, nitride, oxynitride and the like.

As shown in the top view of the semiconductor device 10A in FIG. 1A, the metal structures M0 and BM0 extend in the X direction, and the metal structures M1 and BM1 extend in the Y direction which is vertical to the X direction. In some embodiments, the metal structure M0 can include the power lines M01, M02, M03, M04 and M05 at the front side of the substrate. The power lines M01 to M05 extend in the X direction and are substantially parallel to each other. Each of the power lines M01 to M05 of the metal structure M0 has a width WM0. The power lines M01 to M05 can be electrically connected to different voltages or power supplies. The power lines M01, M03 and M05 can be electrically connected to the voltage VSS for transmitting power to the cells. The power lines M02 and M04 can be electrically connected to the voltage VDDH for transmitting power to the cells. For example, the power line M01 electrically connected to the voltage VSS, and the power line M02 electrically connected to the voltage VDDH can be used to drive the cells 130 and 134.

The metal structure BM0 can include the power lines BM01, BM02, BM03, BM04, BM05, BM06, BM07, BM08 and BM09 at the back side of the substrate. The power lines BM01 to BM09 extend in the X direction and are substantially parallel to each other. Each of the power lines BM01 to BM09 of the metal structure BM0 has a width WBM0. The power lines BM01 to BM09 can be electrically connected to different voltages or power supplies. The power lines BM01, BM05 and BM09 can be electrically connected to the voltage VSS for transmitting power to the cells. The power line BM02 can be electrically connected to the voltage VDDH for transmitting power to the cells. The power lines BM03 and BM07 can be electrically connected to the voltage VDDL for transmitting power to the cells. For example, the power line BM01 electrically connected to the voltage VSS, the power line BM02 electrically connected to the voltage VDDH, and the power line BM03 electrically connected to the voltage VDDL can be used to drive the cell 150. The voltage VDDH can be greater than the voltage VDDL. For example, the voltage VDDH can be greater than the voltage VDDL by 500 mV or less than 500 mV.

In some embodiments, each of the power lines BM01 to BM09 of the metal structure BM0 has a width WBM0. The width WBM0 can be greater than the width WM0. In some embodiments, the power line M01 can overlap with the power line BM01. The power line M01 can be within or surrounded by the power line BM01. The power line M02 can overlap with the power line BM03. The power line M02 can be within or surrounded by the power line BM03. The power line M03 can overlap with the power line BM05. The power line M03 can be within or surrounded by the power line BM05. The power line M04 can overlap with the power line BM07. The power line M04 can be within or surrounded by the power line BM07. The power line M05 can overlap with the power line BM09. The power line M05 can be within or surrounded by the power line BM09. The power lines M01 to M05 can be staggered or interleaved with the power lines BM01 to BM09.

The metal structure M1 can include the power lines M11 and M12 at the front side of the substrate. The power lines M11 and M12 extend in the Y direction and are substantially parallel to each other. Each of the power lines M11 and M12 of the metal structure M1 has a width WM1. The width WM1 can be smaller than the width WBM0. The width WM1 can be substantially identical to the width WM0. The power lines M11 and M12 can be electrically connected to the same voltages. The power lines M11 and M12 can be electrically connected to the voltage VDDH for transmitting power to the cells. The power lines M11 and M12 can be electrically connected to different voltages. The power line M11 can be electrically connected to the voltage VDDH, and the power line M12 can be electrically connected to the voltage VDDL.

The metal structure BM1 can include at least one power line BM11 at the back side of the substrate. The power line BM11 can extend in the Y direction. The power line BM11 of the metal structure BM1 has a width WBM1. The width WBM1 can be smaller than the width WBM0. The width WBM1 can be substantially identical to the widths WM0 and WM1. The power lines BM1, M11 and M12 can be electrically connected to different voltages. The power lines M11 and M12 can be electrically connected to the voltage VDDH, and the power line BM11 can be electrically connected to the voltage VDDL. The power line BM11 can be staggered or interleaved with the power lines M11 and M12.

As shown in FIG. 1A, the cells 130, 131, 132, 133, 134 and 135 are electrically connected to and configured to receive the voltage VDDH. The cells 140, 141, 142, 143, 144, 145, 146 and 147 are electrically connected to and configured to receive the voltage VDDL. The cells 150, 151, 152, 153 and 154 are electrically connected to and configured to receive the voltage VDDH. The cells 130 to 135, 140 to 147, and 150 to 154 can include standard cells, functional cells and head cells. Some of the cells 130 to 135, 140 to 147, and 150 to 154 can be directly electrically connected to execute specific functions. For example, the output O of the cell 135 is electrically connected to the input I of the cell 141.

The semiconductor device 10A also includes a power tap cell 110 and two level shifter cells 120 and 122. The power tap cell 110 can overlap with the power line M12 and the power line BM02. The power tap cell 110 can be provided between two adjacent power lines M01 and M02. The power tap cell 110 can be used to transmit the power from the backside of the substrate through the power line M12 to the power line M01 or M02 of the front side of the substrate.

The level shifter cells 120 and 122 can be used to transfer or convert voltages from the previous-stage circuit to the subsequent-stage circuit, especially when the subsequent-stage circuit requires higher driving voltages than the previous-stage circuit. As shown in FIG. 1A, the level shifter cell 120 is electrically connected between the cell 147 with the relative low voltage VDDL and the cell 151 with the relative high voltage VDDH. The level shifter cell 122 is electrically connected between the cell 142 with the relative low voltage VDDL and the cell 153 with the relative high voltage VDDH.

FIG. 1B is a schematic view of a design layout of another semiconductor device 10B, in accordance with some embodiments of the present disclosure. The semiconductor device 10B of FIG. 1B can be similar to the semiconductor device 10A of FIG. 1A, except for the differences described as follows.

The semiconductor device 10B has no power line from the back side of the substrate. The metal structure M1 of semiconductor device 10B includes three power lines M11, M12 and M13. The power lines M11 and M12 are electrically connected to the voltage VDDH, and the power line M13 is electrically connected to the voltage VDDL. The cells 130 to 135, 140 to 147, and 150 to 154 are driven by or receive the voltages VDDH, VDDL, and VDDH, respectively. The power lines M02 and M04 are electrically connected to the voltage VDDH or VDDL. Since all the power is received from the front side of the substrate, in order to avoid short circuit, the power lines M02 and M04 are divided into multiple sections. The power lines M02 and M04 are in a discreet or non-continuous shape. As shown in FIG. 1B, the power line M02 can include three power line sections M02A, M02B and M02C separated by two break points B1 and B2. The power line sections M02A, M02B and M02C correspond to the power lines M11, M13 and M12 for different voltages VDDH and VDDL. The power line M04 can include three power line sections M04A, M04B and M04C separated by two break points B3 and B4. The power line sections M04A, M04B and M04C correspond to the power lines M11, M13 and M12 for different voltages VDDH and VDDL. However, the break points B1 to B4 can increase the complexity of design layout and degrade the performance of the semiconductor device 10B.

Now please refer to the semiconductor device 10A of FIG. 1A. Both the back side and the front side of the substrate can be used to provide the power supply. The voltage from the back side can be transmitted to the front side by, for example, the power tap cell 110. In addition, the metal structures M0, M1, BM0 and BM1 can be electrically connected to one or more of the voltages VSS, VDDH and VDDL independently, which can provide more flexibility and compatibility of the power line routing. As shown in FIG. 1A, each of the power lines M01 to M05 are in a continuous shape, especially the power lines M02 and M04 electrically connected to the voltage VDDH or VDDL. That is, the power lines M02 and M04 are not required to be divided into multiple sections to avoid short circuit, thereby reducing the complexity of design layout and enhancing the performance of the semiconductor device 10A.

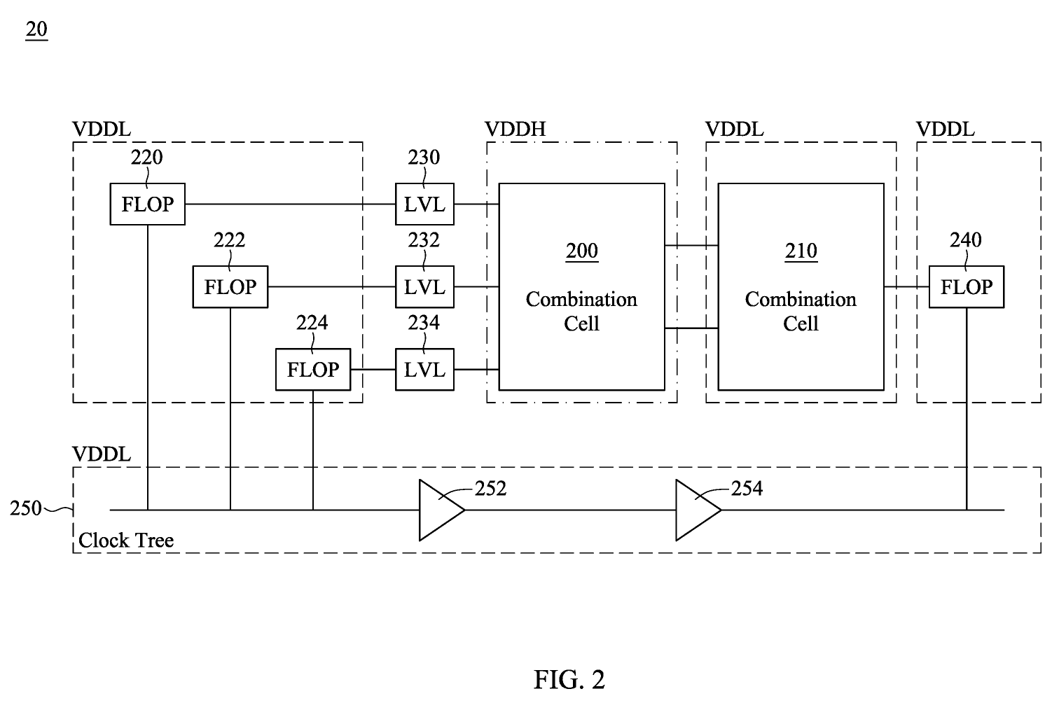

FIG. 2 is a schematic diagram of a semiconductor device 20, in accordance with some embodiments of the present disclosure. The semiconductor device 20 of FIG. 2 can correspond to the semiconductor device 10A of FIG. 1A.

The semiconductor device 20A includes combination cells 200 and 210, level shifter (LVL) cells 230, 232 and 234, flip-flop (FLOP) cells 220, 222, 224 and 240, and a clock tree 250. The flip-flop cells 220, 222 and 224 serving as the first stage are electrically connected to the voltage VDDL instead of the voltage VDDH to reduce power consumption. The combination cells 200 and 210 can include standard cells, functional cells and head cells. The combination cells 200 and 210 are used to receive the voltages VDDH and VDDL, respectively, to reduce the design complexity of the semiconductor device 20. The level shifter cells 230, 232 and 234 are formed between the flip-flop cells 220, 222 and 224 (corresponding to the relative low voltage VDDL) and the combination cell 200 (corresponding to the relative high voltage VDDH). Another flip-flop cell 240 is provided subsequent to the combination cell 210. The flip-flop cell 240 and the combination cell 210 are both electrically connected to the voltage VDDL, and thus no level shifter cell is required therebetween. In addition, the clock tree 250 includes several inverters 252 and 254 electrically connected between the flip-flop cells 220, 222, 224 and 240. The clock tree 250 can be used to provide clock signals for the semiconductor device 20. The high toggle rate of the clock tree 250 can be changed or adjusted to the flip-flop cells 220, 222, 224 and 240 with the voltage VDDL for power saving.

FIG. 3 illustrates a cross-section view of a semiconductor device 30, in accordance with some embodiments of the present disclosure. The semiconductor device 30 of FIG. 3 can correspond to the semiconductor device 10A of FIG. 1A and the semiconductor device 10B of FIG. 1B.

The semiconductor device 30 is used to receive power, such as the voltages VSS and VDD, from the front side of the substrate. The voltage VDD can include the voltages VDDH and VDDL, which are greater than the voltage VSS. The semiconductor device 30 can include metal structures M0, M1 and M2, two metal layers MD1 and MD2, the via structures V1 and V2, and the epitaxial layers EP1 and EP2. Forming the semiconductor device 30 includes performing one or more lithography, deposition, etching, planarizing, or other suitable processes.

The metal structures M0, M1 and M2, and the metal layers MD1 and MD2 can be electrically connected through multiple vias, such as the via structures V1 and V2. The metal layers MD1 and MD2 and the via structures V1 and V2 are made of metal, such as copper, aluminum, tungsten, titanium, tantalum, an alloy thereof or the like, and are electrically insulated by dielectric materials such as oxide, nitride, oxynitride and the like. The epitaxial layers EP1 and EP2 can include at least one semiconductor film with certain fixed crystallographic features, resulting in continuous lattice planes across the interface. The epitaxial layers EP1 and EP2 can be spaced apart and electrically isolated from each other.

As shown in FIG. 3, the voltages VSS and VDD are received from the front side. The voltage VSS is transmitted to the epitaxial layer EP1 through the power lines M21, M11, and M01, the via structure V1, and the metal layer MD1 sequentially. The voltage VDD is transmitted to the epitaxial layer EP2 through the power lines M22, M12, and M02, the via structure V2, and the metal layer MD2 sequentially.

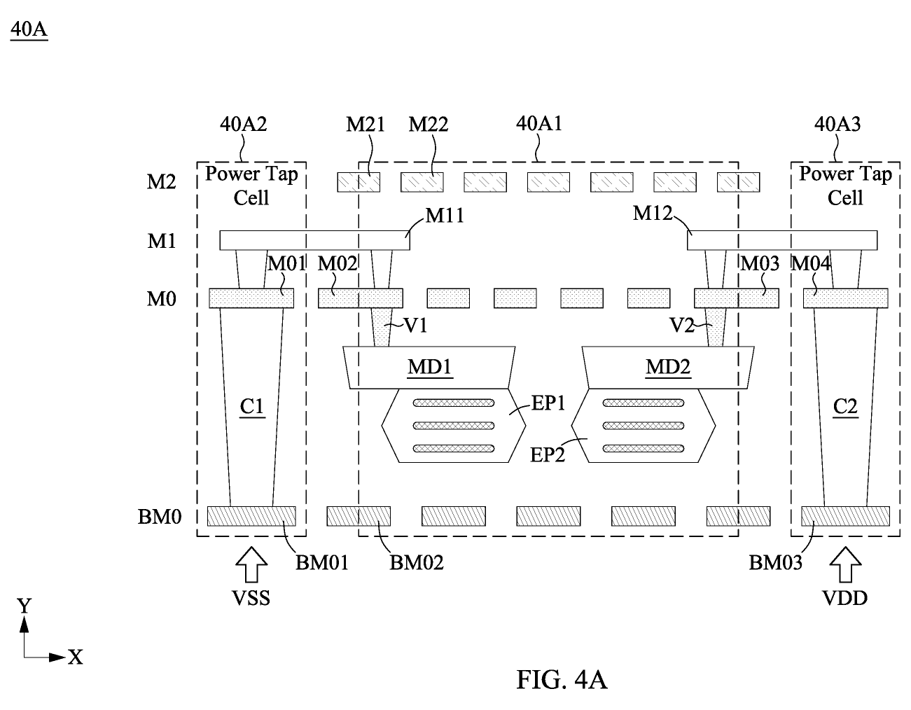

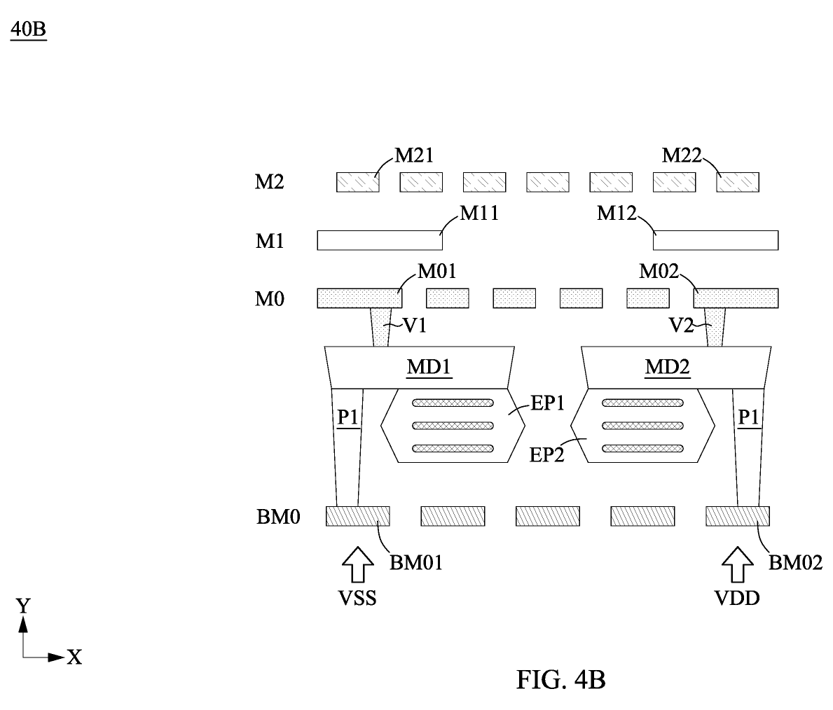

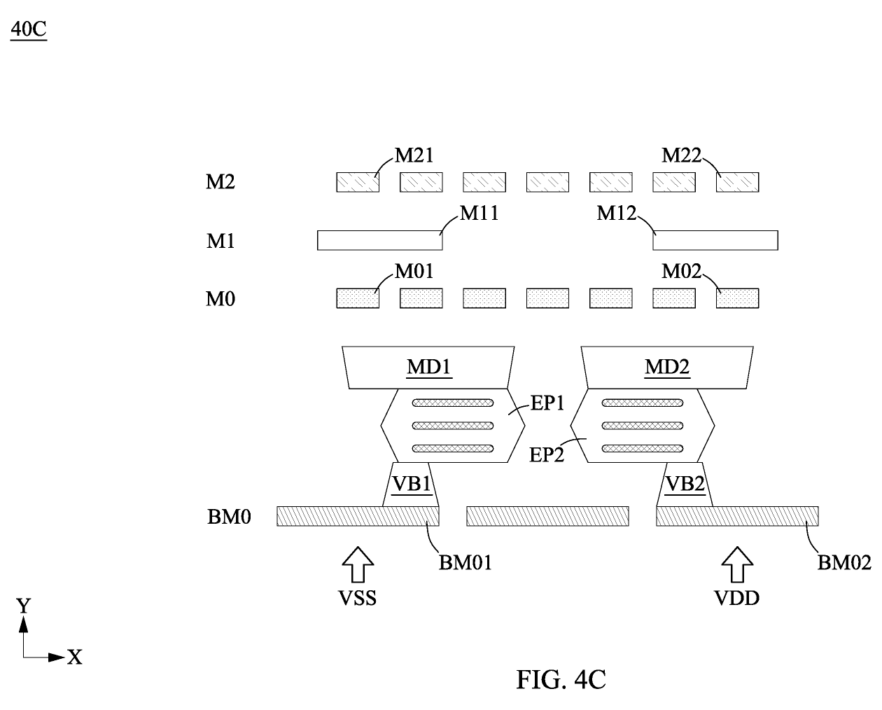

FIG. 4A illustrates a cross-section view of a semiconductor device 40A, in accordance with some embodiments of the present disclosure. The semiconductor device 40A of FIG. 4A can correspond to the semiconductor device 10A of FIG. 1A and the semiconductor device 10B of FIG. 1B.

The semiconductor device 40A is used to receive the voltages VSS and VDD from the back side of the substrate, and then transmit the received voltages VSS and VDD to the front side of the substrate. The semiconductor device 40A includes the cell 40A1, and the power tap cells 40A2 and 40A3. The cell 40A1 can include a standard cell, a functional cell or a head cell. Moreover, forming the semiconductor device 40A includes performing one or more lithography, deposition, etching, planarizing, or other suitable processes. The structural configuration of the cell 40A1 can be similar to the semiconductor device 30 of FIG. 3, and thus will not be repeated hereinafter for conciseness.

The power tap cell 40A2 can be used to transmit the power from the voltage VSS at the back side to the epitaxial layer EP1 of the cell 40A1. A conductive structure C1 is formed between the power lines M01 and BM01. The conductive structure C1 can be made of conductive material, and may include, for example, aluminum, copper, chromium, tin, gold, silver, nickel or stainless steel, or a mixture, an alloy, or other combinations thereof. The voltage VSS can be transmitted through the power line BM01, the conductive structure C1, the power lines M01, M11, M02, the via structure V1, the metal layer MD1, and to the epitaxial layer EP1.

The power tap cell 40A3 can be used to transmit the power from the voltage VDD at the back side to the epitaxial layer EP2 of the cell 40A1. A conductive structure C2 is formed between the power lines M04 and BM03. The conductive structure C2 can be made of conductive material, and may include, for example, aluminum, copper, chromium, tin, gold, silver, nickel or stainless steel, or a mixture, an alloy, or other combinations thereof. The voltage VDD can be transmitted through the power line BM03, the conductive structure C2, the power lines M04, M12, M03, the via structure V2, the metal layer MD2, and to the epitaxial layer EP2.

FIG. 4B illustrates a cross-section view of another semiconductor device 40A, in accordance with some embodiments of the present disclosure. The semiconductor device 40B of FIG. 4B can correspond to the semiconductor device 10A of FIG. 1A and the semiconductor device 10B of FIG. 1B.

The semiconductor device 40B is used to receive the voltages VSS and VDD from the back side of the substrate, and then transmit the received voltages VSS and VDD to the epitaxial layers EP1 and EP2. The semiconductor device 40B can include a standard cell, a functional cell or a head cell. Forming the semiconductor device 40B includes performing one or more lithography, deposition, etching, planarizing, or other suitable processes.

The semiconductor device 40B can be used to transmit the power from the voltage VSS at the back side to the epitaxial layer EP1. A power via P1 is formed between the power line BM01 and the metal layer MD1. The power via P1 can be made of conductive material, and may include, for example, aluminum, copper, chromium, tin, gold, silver, nickel or stainless steel, or a mixture, an alloy, or other combinations thereof. The voltage VSS can be transmitted through the power line BM01, the power via P1, the metal layer MD1, and to the epitaxial layer EP1.

In addition, the semiconductor device 40B can be used to transmit the power from the voltage VDD at the back side to the epitaxial layer EP1. A power via P2 is formed between the power line BM02 and the metal layer MD2. The power via P2 can be made of conductive material, and may include, for example, aluminum, copper, chromium, tin, gold, silver, nickel or stainless steel, or a mixture, an alloy, or other combinations thereof. The voltage VDD can be transmitted through the power line BM02, the power via P2, the metal layer MD2, and to the epitaxial layer EP2.

FIG. 4C illustrates a cross-section view of another semiconductor device 40C, in accordance with some embodiments of the present disclosure. The semiconductor device 40C of FIG. 4C can correspond to the semiconductor device 10A of FIG. 1A and the semiconductor device 10B of FIG. 1B. The semiconductor device 40C is used to receive the voltages VSS and VDD from the back side of the substrate, and then transmit the received voltages VSS and VDD to the epitaxial layers EP1 and EP2. The semiconductor device 40C can include a standard cell, a functional cell or a head cell. Forming the semiconductor device 40C includes performing one or more lithography, deposition, etching, planarizing, or other suitable processes.

The semiconductor device 40C can be used to transmit the power from the voltage VSS at the back side to the epitaxial layer EP1. A metal structure VB1 is formed between the power line BM01 and the epitaxial layer EP1. The metal structure VB1 can be made of conductive material, and may include, for example, aluminum, copper, chromium, tin, gold, silver, nickel or stainless steel, or a mixture, an alloy, or other combinations thereof. The voltage VSS can be transmitted through the power line BM01, the metal structure VB1, and to the epitaxial layer EP1.

In addition, the semiconductor device 40C can be used to transmit the power from the voltage VDD at the back side to the epitaxial layer EP2. A metal structure VB2 is formed between the power line BM02 and the epitaxial layer EP2. The metal structure VB2 can be made of conductive material, and may include, for example, aluminum, copper, chromium, tin, gold, silver, nickel or stainless steel, or a mixture, an alloy, or other combinations thereof. The voltage VDD can be transmitted through the power line BM02, the metal structure VB2, and to the epitaxial layer EP2.

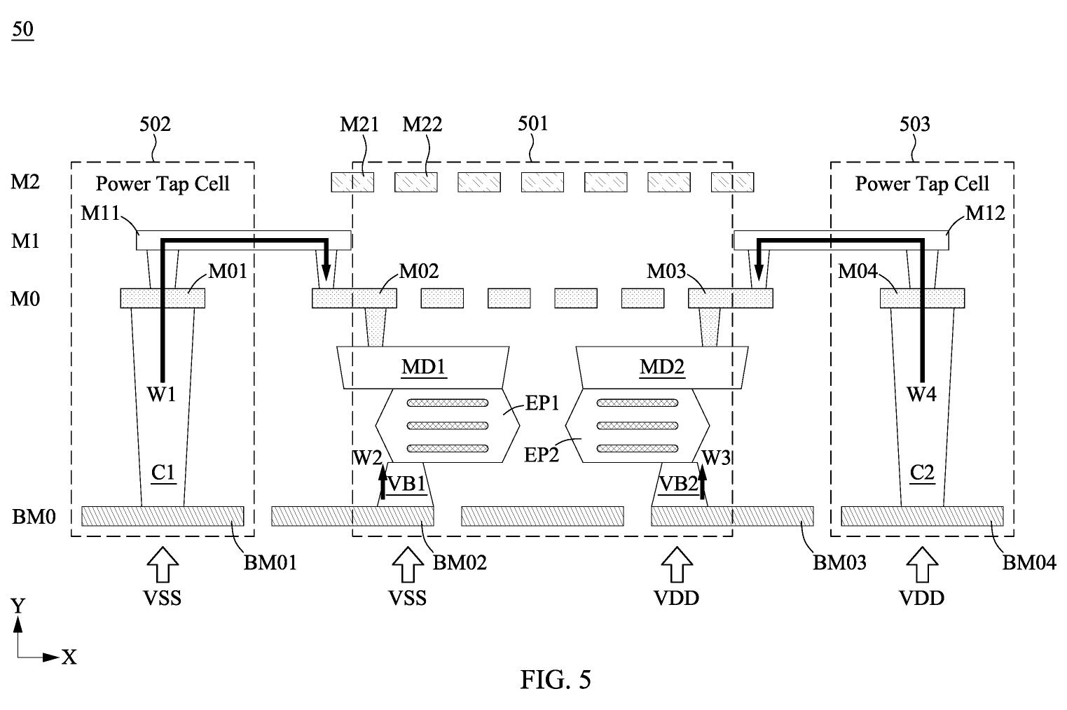

FIG. 5 illustrates a cross-section view of a semiconductor device 50, in accordance with some embodiments of the present disclosure. The semiconductor device 50 of FIG. 5 can correspond to the semiconductor device 10A of FIG. 1A, the semiconductor device 40A of FIG. 4A, and the semiconductor device 40B of FIG. 4B.

The semiconductor device 50 is used to receive the voltages VSS and VDD from the back side of the substrate, and then transmit the received voltages VSS and VDD to the front side of the substrate. Furthermore, the semiconductor device 50 is used to receive the voltages VSS and VDD from the back side of the substrate, and then transmit the received voltages VSS and VDD directly to the epitaxial layers EP1 and EP2. The semiconductor device 50 includes the cell 501, and the power tap cells 502 and 503. The cell 501 can include a standard cell, a functional cell or a head cell.

In some embodiments, the power tap cell 502 can be similar to the power tap cell 40A2 of FIG. 4A for transmitting the power W1 from the back side to the front side, and the power tap cell 503 can be similar to the power tap cell 40A3 of FIG. 4A for transmitting the power W4 from the back side to the front side. In the embodiment of FIG. 5A, the power W1 corresponds to the voltage VSS. In other embodiments, the power W1 can correspond to the voltage VDDH or VDDL. In the embodiment of FIG. 5A, the power W4 corresponds to the voltage VDD. In other embodiments, the power W4 can correspond to the voltage VSS.

In some embodiments, the cell 501 can be similar to the semiconductor device 40C of FIG. 4C for directly transmitting the power W2 and W3 from the back side to the epitaxial layers EP1 and EP2. In the embodiment of FIG. 5A, the power W2 corresponds to the voltage VSS. In other embodiments, the power W2 can correspond to the voltage VDDH or VDDL. In the embodiment of FIG. 5A, the power W3 corresponds to the voltage VDD. In other embodiments, the power W3 can correspond to the voltage VSS. Based on the foregoing, the present disclosure can provide different design scenarios based on need. In some embodiments, one or two of the voltages VSS, VDDH and VDDL can be selected or applied for driving different cells. Furthermore, two power transmission paths are also provided by the present disclosure, including the transmission from the back side to the front side, and the direct transmission to the back side. Each power transmission path can be utilized in association with any one of the voltages VSS, VDDH and VDDL, thereby enhancing circuit design flexibility and manufacturing efficiency.

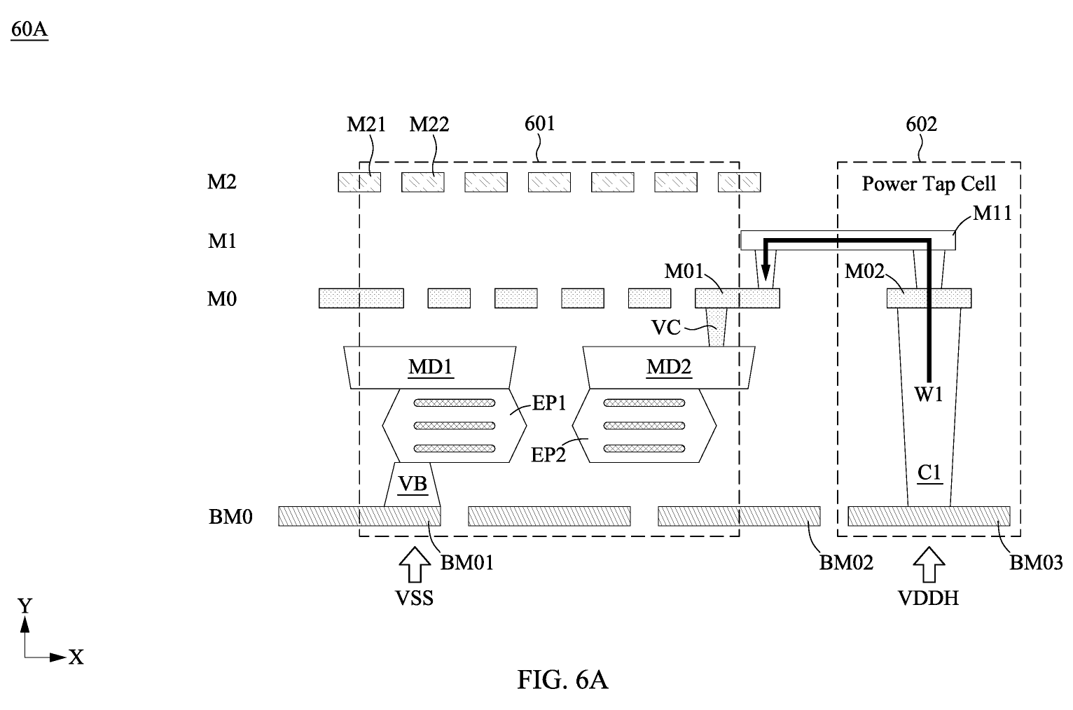

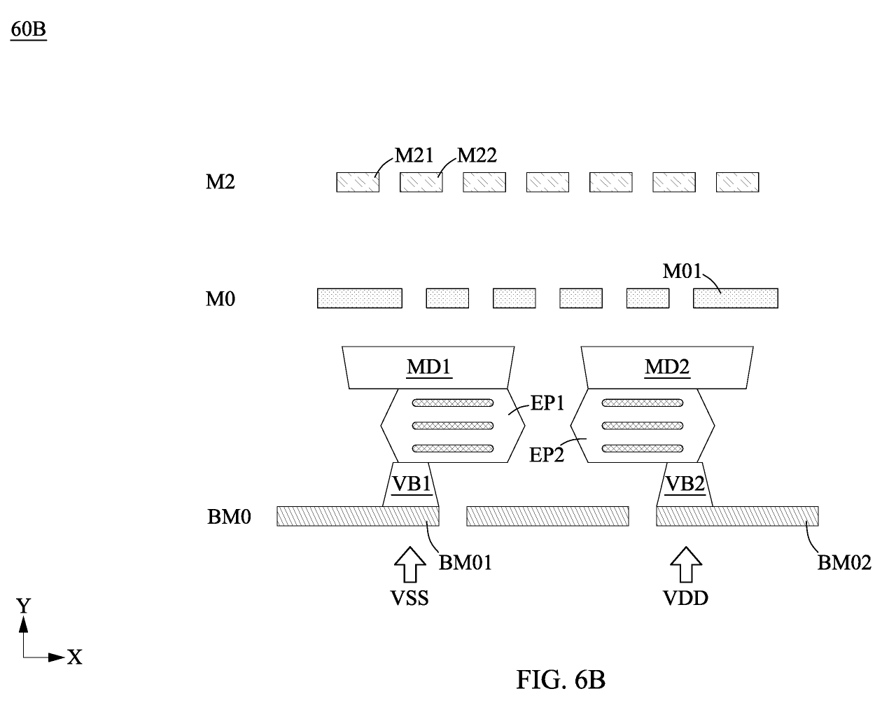

FIG. 6A illustrates a cross-section view of a semiconductor device 60A, in accordance with some embodiments of the present disclosure. FIG. 6B illustrates a cross-section view of the semiconductor device 60A, in accordance with some embodiments of the present disclosure. In some embodiments, the semiconductor device 60A can include a VDDH cell driven by the voltage VDDH, and the semiconductor device 60B can include a VDDL cell driven by the voltage VDDL.

As shown in FIG. 6A, the voltage VDDH can be transmitted from the back side through the front side by the power tab cell 602 and to the epitaxial layer EP2 of the cell 601. The voltage VSS can be transmitted from the back side to the epitaxial layer EP1 through the metal structure VB without passing through the front side. In addition, as shown in FIG. 6B, the voltage VSS can be transmitted from the back side to the epitaxial layer EP1 through the metal structure VB1 without passing through the front side. The voltage VDDL can be transmitted from the back side to the epitaxial layer EP2 through the metal structure VB2 without passing through the front side.

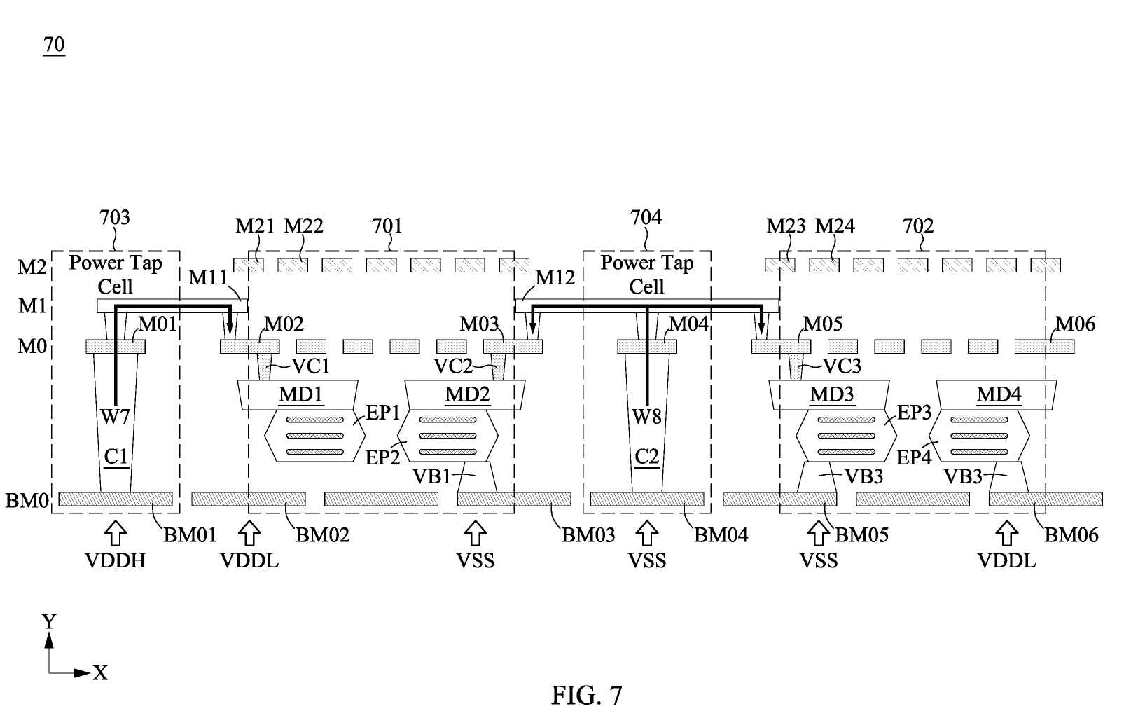

FIG. 7 illustrates a cross-section view of a semiconductor device 70, in accordance with some embodiments of the present disclosure. The semiconductor device 70 includes two cells 701 and 702 and two power tap cells 703 and 704. The semiconductor device 70 can be similar to the semiconductor device 60A in FIG. 6A and the semiconductor device 60B in FIG. 6B, and thus a detailed description thereof is omitted for brevity.

The power tap cell 703 can be used to transmit power W7 from the voltage VDDH at the back side through the power line M11 at the front side to the epitaxial layer EP1 of the cell 701. The power tap cell 704 is formed between the cells 701 and 702. The power tap cell 704 can be shared by the cells 701 and 702. The power tap cell 704 can be used to transmit power W8 from the voltage VSS at the back side through the power line M12 at the front side to both the epitaxial layer EP2 of the cell 701 and the epitaxial layer EP6 of the cell 702, thereby reducing design complexity and manufacturing costs of the semiconductor device 70. In addition, the present disclosure can also provide mixed threshold voltage design within a block. The block can represent or correspond to an electronic component with certain function, such as a high-speed processor or a low-speed processor. Compared to multiple VDD design across blocks, the mixed threshold voltage design within a block can be used to further decrease the leakage current of the semiconductor device.

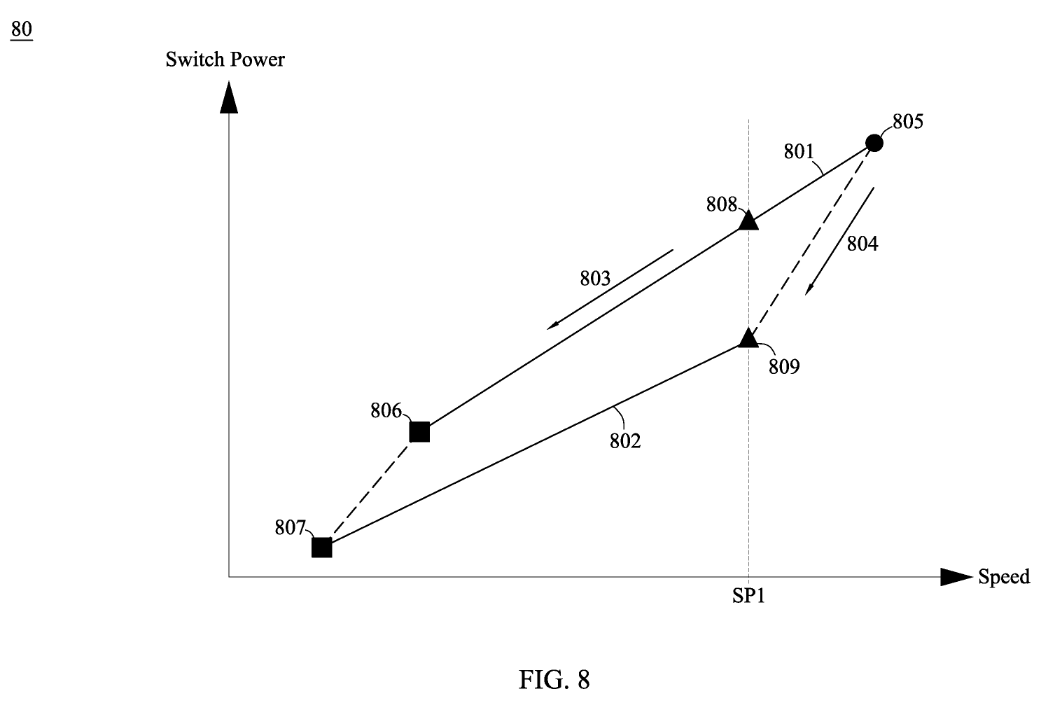

FIG. 8 is a schematic diagram illustrating a graph 80 of the speed and switch power of a semiconductor device, in accordance with some embodiments of the present disclosure. The graph 80 includes two curves 801 and 802. In some embodiments, the curve 801 corresponds to high voltage VDD, such as the voltage VDDH. The curve 802 corresponds to low voltage VDD, such as the voltage VDDL. The two points 805 and 806 of the curve 801 correspond to large and small widths of the active region of the semiconductor device. Given the same voltage VDDH, the speed and switch power can change along the direction 803 as the width of the active region decreases. In addition, the two points 809 and 807 of the curve 802 correspond to large and small widths of the active region of the semiconductor device.

In some embodiments, along the direction 804, by modifying the width of the active region and decreasing the voltage VDD, the switch power can be reduced but the speed is also decreased. In some embodiments, by decreasing the voltage VDD from point 808 to the point 809 at the same speed SP1, the switch power can be reduced while maintaining the same speed. The present disclosure can provide various power transmission path associated with various voltages VSS, VDDH and VDDL, thereby enhancing circuit design flexibility and reducing the switch power without sacrificing speed.

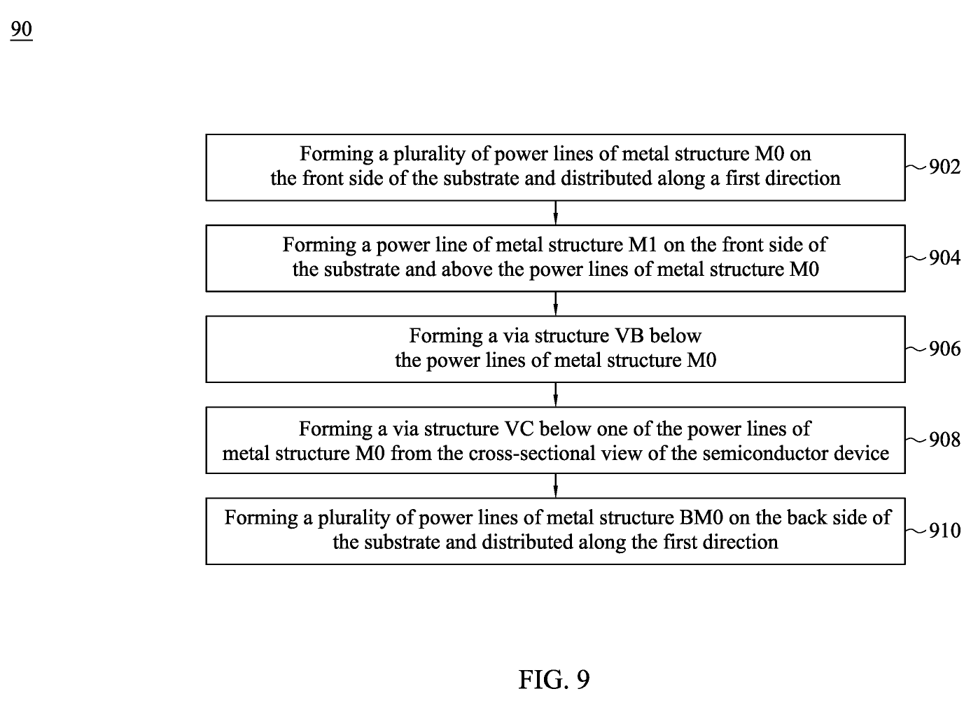

FIG. 9 illustrates a flow chart 90 including a method for manufacturing the semiconductor device, in accordance with some embodiments of the present disclosure. In operation 902, a plurality of power lines of metal structure M0 are formed on the front side of the substrate and distributed along a first direction. In operation 904, a power line of metal structure M1 is formed on the front side of the substrate and above the power lines of metal structure M0. In operation 906, a via structure VB is formed below the power lines of metal structure M0. In operation 908, a via structure VC is formed below one of the power lines of metal structure M0 from the cross-sectional view of the semiconductor device. In operation 910, a plurality of power lines of metal structure BM0 are formed on the back side of the substrate and distributed along the first direction.

While the disclosed flow chart 90 is illustrated and described below as a series of acts or events, it will be appreciated that the illustrated ordering of such acts or events are not to be interpreted in a limiting sense. For example, some operations may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

Some embodiments of the present disclosure provide a semiconductor device. The semiconductor device includes a plurality of first power lines, a plurality of second power lines, a plurality of third power lines and a power tap cell. The first power lines are formed on a front side of a substrate and extend in a first direction. The first power lines are electrically connected to a first set of cells and a second set of cells. The first set of cells are configured to receive a first voltage, and the second set of cells are configured to receive a second voltage smaller than the first voltage. The second power lines are formed on the front side of the substrate, extend in a second direction vertical to the first direction, and are electrically connected to the first set of cells. The third power lines are formed on a back side of the substrate, extend in the first direction, and are electrically connected to the first set of cells and the second set of cells. The power tap cell overlaps one of the second power lines and one of the third power lines from a top view of the semiconductor device. The power tap cell is configured to transmit power from the back side to the front side.

Some embodiments of the present disclosure provide a semiconductor device. The semiconductor device includes a plurality of first power lines, a first via structure, a plurality of second power lines and a second via structure. The first power lines are formed on a back side of a substrate and distributed along a first direction. The first via structure is formed above one of the first power lines from a cross-sectional view of the semiconductor device. The first via structure and its corresponding first power line are electrically connected to a first voltage. The second power lines are formed on a front side of the substrate and distributed along the first direction. The second via structure is formed below one of the second power lines from the cross-sectional view of the semiconductor device. The second via structure and its corresponding second power line are electrically connected to a second voltage.

Some embodiments of the present disclosure provide a method for manufacturing a semiconductor device. The method includes forming a plurality of first power lines on a front side of a substrate and distributed along a first direction, forming a first via structure below the first power lines from a cross-sectional view of the semiconductor device, and forming a plurality of second power lines on a back side of the substrate and distributed along the first direction. The first via structure is formed above one of the second power lines from the cross-sectional view of the semiconductor device, and the first via structure and its corresponding second power line are electrically connected to a first voltage.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of first power lines formed on a front side of a substrate and extending in a first direction, electrically connected to a first set of cells and a second set of cells, wherein the first set of cells are configured to receive a first voltage, and the second set of cells are configured to receive a second voltage smaller than the first voltage;
a plurality of second power lines formed on the front side of the substrate and extending in a second direction vertical to the first direction, electrically connected to the first set of cells;
a plurality of third power lines formed on a back side of the substrate and extending in the first direction, electrically connected to the first set of cells and the second set of cells; and
a power tap cell, overlapping one of the second power lines and one of the third power lines from a top view of the semiconductor device, wherein the power tap cell is configured to transmit power from the back side to the front side.

2. The semiconductor device of claim 1, wherein each of the first power lines is in a continuous shape.

3. The semiconductor device of claim 1, further comprising:
a plurality of fourth power lines formed on the back side of the substrate and extending in the second direction, electrically connected to the second set of cells.

4. The semiconductor device of claim 3, wherein the fourth power lines are formed below the third power lines from the cross-sectional view of the semiconductor device.

5. The semiconductor device of claim 1, further comprising:
a level shifter cell, electrically connected between an output of one of the second set of cells and an input of one of the first set of cells.

6. The semiconductor device of claim 1, wherein the second power lines are formed above the first power lines from the cross-sectional view of the semiconductor device.

7. The semiconductor device of claim 1, wherein a width of each of the third power lines is greater than a width of each of the first power lines and the second power lines.

8. A semiconductor device, comprising:
a plurality of first power lines formed on a back side of a substrate and distributed along a first direction;
a first via structure, formed above one of the first power lines from a cross-sectional view of the semiconductor device, wherein the first via structure and its corresponding first power line are electrically connected to a first voltage;
a plurality of second power lines formed on a front side of the substrate and distributed along the first direction; and
a second via structure, formed below one of the second power lines from the cross-sectional view of the semiconductor device, wherein the second via structure and its corresponding second power line are electrically connected to a second voltage.

9. The semiconductor device of claim 8, wherein the second voltage is greater than the first voltage.

10. The semiconductor device of claim 8, further comprising:
a third power line formed on the front side of the substrate and electrically connected to the second via structure, wherein the third power line is disposed above the second power lines from the cross-sectional view of the semiconductor device.

11. The semiconductor device of claim 10, further comprising:
a first conductive structure, extending in a second direction vertical to the first direction, wherein the first conductive structure is electrically connected to the third power line and the second voltage.

12. The semiconductor device of claim 10, further comprising:
a third via structure, formed above one of the first power lines from the cross-sectional view of the semiconductor device, wherein the third via structure and its corresponding second power line are electrically connected to a third voltage.

13. The semiconductor device of claim 12, wherein the second voltage and the third voltage are greater than the first voltage.

14. The semiconductor device of claim 12, further comprising:
a fourth power line formed on the front side of the substrate, wherein the fourth power line is at the same elevation level with the third power line from the cross-sectional view of the semiconductor device.

15. The semiconductor device of claim 14, further comprising:
two second conductive structures, extending in the second direction, wherein the second conductive structures are electrically connected to the fourth power line and the first voltage.

16. The semiconductor device of claim 15, wherein the fourth power line is shared by two cells electrically connected to the second voltage and the third voltage, respectively, one of the two cells comprises one of the two second conductive structures, and the other one of the two cells comprises the other one of the two second conductive structures.

17. The semiconductor device of claim 8, wherein each of the second power lines is in a continuous shape.

18. A method for manufacturing a semiconductor device, comprising:
forming a plurality of first power lines on a front side of a substrate and distributed along a first direction;
forming a first via structure below the first power lines from a cross-sectional view of the semiconductor device;
forming a plurality of second power lines on a back side of the substrate and distributed along the first direction, wherein the first via structure is formed above one of the second power lines from the cross-sectional view of the semiconductor device, and the first via structure and its corresponding second power line are electrically connected to a first voltage.

19. The method of claim 18, further comprising:
forming a second via structure below one of the first power lines from the cross-sectional view of the semiconductor device, wherein the second via structure and its corresponding first power line are electrically connected to a second voltage.

20. The method of claim 19, further comprising:
forming a third power line on the front side of the substrate and electrically connected to the second via structure, wherein the third power line is disposed above the first power lines from the cross-sectional view of the semiconductor device.
